(19) United States
(12) Patent Application Publication
(10) Pub. No.: US 2013/0141123 A1
(43) Pub. Date: Jun. 6, 2013

(54) PH-METER CAPABLE OF MEASURING CONDUCTIVITY AND DISSOLVED OXYGEN SIMULTANEOUSLY

(71) Applicant: Chen-Heng CHENG, Taichung City (TW)

(72) Inventor: Chen-Heng CHENG, Taichung City (TW)

(73) Assignee: AZ INSTRUMENT CORP., Taichung City (TW)

(21) Appl. No.: 13/367,445

(22) Filed: Feb. 7, 2012

(30) Foreign Application Priority Data
Dec. 5, 2011 (TW) 100144695

(51) Int. Cl. G01R 27/08

(52) U.S. Cl. 324/724

(57) ABSTRACT

A pH-meter capable of measuring conductivity and dissolved oxygen at the same time is composed of a gauge and three probes. Three power sources and three measuring circuits are mounted to the gauge. The detectors of the probes include a pH detector, a conductivity detector and a dissolved oxygen detector. Each of the probes is independently connected with the gauge via a transmission cable to be independently supplied with electricity and the signals of two probes are independently transmitted by electric insulation. Thus, the detecting elements can measure the pH value, conductivity, and dissolved oxygen at the same time with interference with one another.

### BACKGROUND OF THE INVENTION

1. Field of the Invention

The present invention relates generally to the technology of measuring chemical property of aqueous solution, and more particularly to a pH-meter capable of measuring conductivity and dissolved oxygen at the same time.

2. Description of the Related Art

A conventional pH-meter capable of measuring conductivity and dissolved oxygen of aqueous solution, as disclosed in U.S. Pat. No. 5,103,179 includes a probe and a meter. The probe is internally installed with a temperature detector, a dissolved oxygen detector, an conductivity detector, and a pH detector. Each of the probe and the meter is installed internally with a plurality of switchers.

A user can insert the probe into an aqueous sample for measuring the temperature, dissolved oxygen, conductivity, and pH value of the aqueous sample. The switchers can stagger the operating time of the aforesaid detectors to prevent the detectors from interference with one another. However, staggering the operating time of the detectors can elongate the time of measuring the aqueous sample to slow the measuring speed, so further improvement is needed.

### SUMMARY OF THE INVENTION

The primary objective of the present invention is to provide a pH-meter, which can measure the conductivity and dissolved oxygen of an aqueous sample at the same time without mutual interference.

The foregoing objective of the present invention is attained by the pH-meter composed of a gauge, a first probe, and a second probe. The gauge includes a housing, a main circuit mounted to the housing, a first measuring circuit, a second measuring circuit, an electric insulator, a user interface, a first power source, and a second power source. The gauge, the first measuring circuit, and the user interface are electrically connected with the first power source. The second measuring circuit is electrically connected with the second power source. The electric insulator is mounted between the second measuring circuit and the main circuit. The signals between the second measuring circuit and the main circuit are transmitted via the electric insulator. The first probe includes a first shell, a first transmission cable, and a first detecting element. The first shell is connected with the housing of the gauge through the first transmission cable. The first detecting element is electrically connected with the first measuring circuit. The second probe includes a second shell, a second transmission cable, and a second detecting element. The second shell of the second probe is connected with the housing of the gauge through the second transmission cable. The second detecting element is electrically connected with the second measuring circuit. The first and second detecting elements are a set of a conductivity detector and a pH detector, or a set of a dissolved oxygen detector and a pH detector.

In a preferred embodiment of the present invention, pH-meter further includes a third probe having a third shell, a third transmission cable, and a third detecting element. The third shell is connected with the housing via the third transmission cable. The gauge further includes a third measuring circuit and a third power source. The third measuring circuit is electrically connected with the third detecting element and the third power source. There are two electric insulators, one of which is mounted between the second measuring circuit and the main circuit and the other is mounted between the third measuring circuit and the main circuit. The first, second, and third detection elements are a set of a pH detector, a conductivity detector and a dissolved oxygen detector. The electric insulator is a photo coupler.

### BRIEF DESCRIPTION OF THE DRAWINGS

FIG. 1 is a schematic view of a preferred embodiment of the present invention.

FIG. 2 is a block diagram of the preferred embodiment of the present invention.

### DETAILED DESCRIPTION OF PREFERRED EMBODIMENTS

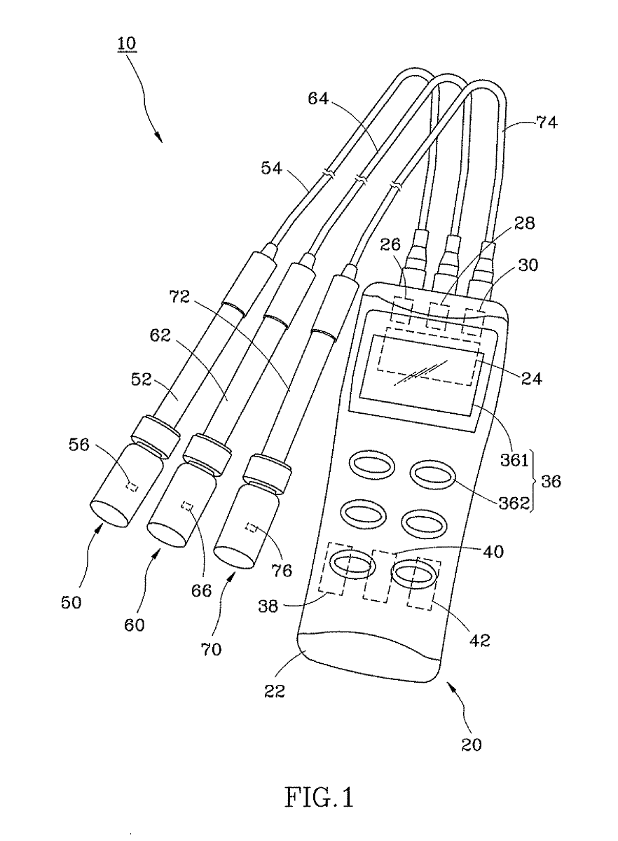

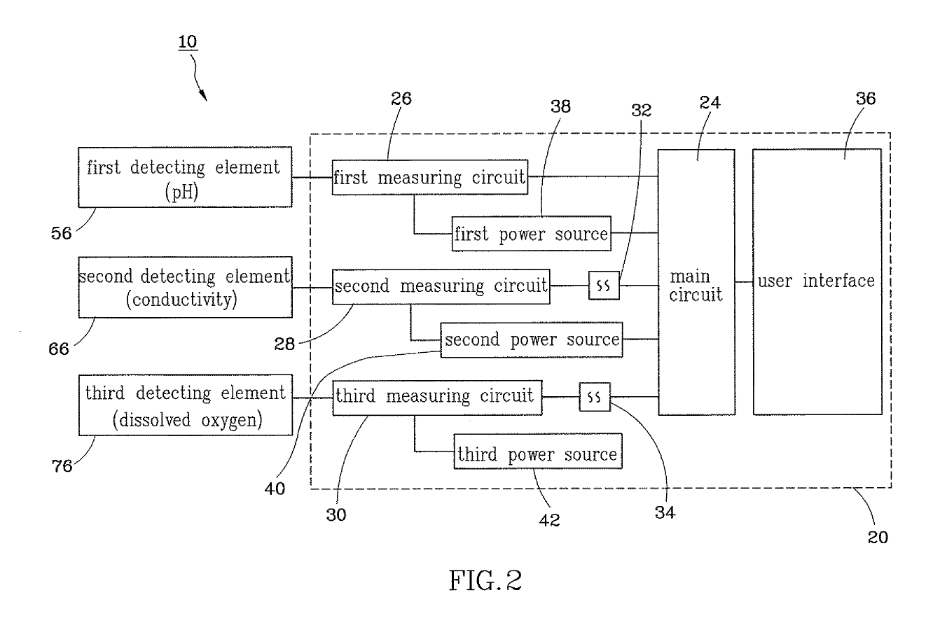

Referring to FIGS. 1-2, a pH-meter 10 capable of measuring conductivity and dissolved oxygen at the same time in accordance with a preferred embodiment of the present invention is composed of a gauge 20, a first probe, 50, a second probe 60, and a third probe 70. The detailed descriptions and operations of these elements as well as their interrelations are recited in the respective paragraphs as follows.

The gauge 20 includes a housing 22, to which a main circuit 24, a first measuring circuit 26, a second measuring circuit 28, a third measuring circuit 30, two electric insulators 32, 34, a user interface 36, a first power source 38, a second power source 40, and a third power source 42 are mounted. The main circuit 24, the first measuring circuit 26, and the user interface 36 are electrically connected with the first power source 38. The second and third measuring circuits 28 and 30 are electrically connected with the second and third power sources 40, 42 separately. The electric insulator 32 is mounted between the second measuring circuit 28 and the main circuit 24 and the other electric insulator 34 is mounted between the third measuring circuit 30 and the main circuit 24. The user interface 36 has a screen 361 and a plurality of press-buttons 362.

Each of the main circuit 24 and the first, second, and third measuring circuits 26, 28, 30 is a printed circuit board (PCB). Each of the electric insulators 32 and 34 is a photo coupler. Each of the electric insulators 32 and 34 contains two optical emitters (not shown) and two optical receivers (not shown) for signal transmission between the second measuring circuit 28 and the main circuit 24 and between the third measuring circuit 30 and the main circuit 24.

Each of the first, second, and third probes 50, 60, 70 includes a shell 52, 62, 72, a transmission cable 54, 64, 74 and a detecting element 56, 66, 76. The shells 52, 62, 72 are connected with the housing 22 via the transmission cable 54, 64, 74. The detecting elements 56, 66, 76 are electrically connected with the first, second, and third measuring circuits 26, 28, 30 separately and are a pH detector, an conductivity detector, and a dissolved oxygen detector separately.

When the probes 50, 60, 70 are inserted into an aqueous sample (not shown), which is to be tested, the detecting elements 56, 66, 76 can output circuit signals to the measuring circuits 26, 28, 30 according to the pH, conductivity, and dissolved oxygen concentration separately. Later, the measuring circuits 26, 28, 30 can decode the circuit signals and then display the outcome on the screen 361 through the main circuit 22.

Because the detecting elements 56, 66, 76 are independently supplied with electricity and the signals are transmitted between the second and third measuring circuits 28, 30 and the main circuit 24 by electrical insulation, even though the detecting elements 56, 66, 76 are working at the same time, their signal transmission can avoid interference with one another. Thus, the simultaneous measurement of conductivity, dissolved oxygen, and pH value is possible and capable of enhancing the measuring speed and convenience.

In addition, when either of the detecting elements 56, 66, 76 is damaged, the user only needs to replace one of the probes 50, 60, 70. Thus, the pH-meter 10 of the present invention needs less maintenance cost when one of the detecting elements is damaged.

The manufacturers can only install two probes, two measuring circuits, and two power sources into the pH-meter, wherein the detecting elements of the two probes can be a set of a conductivity detector and a pH detector, or a set of a dissolved oxygen detector and a pH detector. The signals between one of the measuring circuits and the main circuit are transmitted by electrical insulation.

Alternatively, the electric insulators 32 and 34 can also be magnetism-transmission elements, such as excitation coils, Hall components, relays, or the combination thereof, not limited to light couplers.

The manufacturers can further install an amplification circuit (not shown) on the first probe 50 to amplify weak pH-signals and transmit the amplified pH-signals to the first measuring circuit 26 via the first transmission cable 54 to prevent the pH-signals from interference of circumferential noises.

Although the present invention has been described with respect to a specific preferred embodiment thereof, it is in no way limited to the specifics of the illustrated structures but changes and modifications may be made within the scope of the appended claims.

What is claimed is:

1. A pH-meter capable of measuring conductivity and dissolved oxygen simultaneously, comprising:
a gauge having a housing, to which a main circuit, a first measuring circuit, a second measuring circuit, at least one electric insulator, a user interface, a first power source, and a second power source are mounted thereof, the main circuit, the first measuring circuit, and the user interface being electrically connected with the first power source, the second measuring circuit being electrically connected with the second power source, the electric insulator being mounted between the second measuring circuit and the main circuit, signals between the second measuring circuit and the main circuit being transmitted via the electric insulator;
a first probe having a first shell, a first transmission cable, and a first detecting element, the first shell being connected with the housing of the gauge via the first transmission cable, the first detecting element being electrically connected with the first measuring circuit of the gauge; and
a second probe having a second shell, a second transmission cable, and a second detecting element, the second shell being connected with the housing of the gauge via the second transmission cable, the second detecting element being electrically connected with the second measuring circuit of the gauge;
wherein the first and second detecting elements are a set of a conductivity detector and a pH detector, or a set of a dissolved oxygen detector and a pH detector.

2. The pH-meter as defined in claim 1 further comprising a third probe having a third shell, a third transmission cable, and a third detecting element, the third shell being connected with the housing of the gauge via the third transmission cable, the gauge having a third measuring circuit and a third power source, the third measuring circuit being electrically connected with the third detecting element and the third power source, the at least one electric insulator being two in number, one of the electric insulators being mounted between the second measuring circuit and the main circuit and the other being mounted between the third measuring circuit and the main circuit, the first, second, and third detecting elements are a set of a pH detector, a conductivity detector and a dissolved oxygen detector.

3. The pH-meter as defined in claim 1, wherein the at least one electric insulator is a photo coupler.
